(19) United States
(12) Patent Application Publication
(10) Pub. No.: US 2010/0059101 A1
(43) Pub. Date: Mar. 11, 2010

(54) PHOTOVOLTAIC DEVICE AND MANUFACTURING METHOD OF PHOTOVOLTAIC DEVICE

(75) Inventor: Wataru Shinohara, Ohgaki City (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/557,104

(22) Filed: Sep. 10, 2009

(30) Foreign Application Priority Data
Sep. 10, 2008 (JP) 2008-231952
Sep. 10, 2008 (JP) 2008-231953

(51) Int. Cl. H01L 31/042; H01L 31/18

(52) U.S. Cl. 136/244; 438/67; 257/E21.499

(57) ABSTRACT

A photovoltaic device is provided comprising an a-Si unit in which a plurality of a-Si cells are connected in series over a transparent insulating substrate, and a μc-Si unit in which a plurality of μc-Si cells having an optical band gap which differs from that of the a-Si cell are connected in series over a substrate, wherein a light-transmissive inorganic insulating layer is formed over at least one of the a-Si unit and the μc-Si unit, and the a-Si unit and the μc-Si unit are fixed by a light-transmissive resin layer while the a-Si unit and the μc-Si unit are opposed to each other in opposite integration directions with the transparent insulating substrate and the substrate being at outer sides.

### CROSS-REFERENCE TO RELATED APPLICATIONS

The entire disclosure of Japanese Patent Application Nos. 2008-231952 and 2008-231953 including specification, claims, drawings, and abstract is incorporated herein by reference.

### BACKGROUND OF THE INVENTION

1. Field of the Invention

The present invention relates to a photovoltaic device and a method of manufacturing a photovoltaic device.

2. Description of the Related Art

Solar batteries which use polycrystalline silicon, microcrystalline silicon, or amorphous silicon are known. In particular, photovoltaic devices which use a thin film of microcrystalline silicon or amorphous silicon have attracted much attention from viewpoints of resource consumption, cost reduction, and improved efficiency.

In general, a thin film photovoltaic device is formed by layering, over a substrate having an insulating surface, a first electrode, one or more semiconductor thin film opto-electric conversion cells, and a second electrode in this order. The opto-electric conversion cell is formed by layering a P-type layer, an I-type layer, and an N-type layer from the side of incidence of light.

As a method of improving the conversion efficiency of the thin film photovoltaic device, a method is known in which two or more types of opto-electric conversion cells are layered in a direction of incidence of light. A first photovoltaic unit comprising an opto-electric conversion layer having a wide band gap is placed on the side of incidence of light of the photovoltaic device, and then, a second photovoltaic unit having an opto-electric conversion layer having a narrower band gap than the first photovoltaic unit is placed. With this structure, opto-electric conversion over a wide wavelength range of the incident light is enabled, and the conversion efficiency of the overall device can be improved.

For example, a structure is known in which an amorphous silicon (a-Si) opto-electric conversion cell is set as a top cell and a microcrystalline silicon (μc-Si) opto-electric conversion cell is set as a bottom cell.

In addition, as shown in FIG. 12, a technique is known in which a top cell 10 and a bottom cell 12 are layered, from the side of the incidence of light, in multiple layers with a transparent insulating film 14 therebetween, and an area of the cell is adjusted such that Sn×Jn is a constant among layers when the effective area of one cell is Sn and the operation current density of the cell is Jn.

In a structure having a top cell and a bottom cell joined, it is desired to improve the light confinement effect in order to further improve the opto-electric conversion efficiency.

In addition, when the transparent insulating film 14 sandwiched between the top cell and the bottom cell is thinned, the isolation voltage between the top cell 10 and the bottom cell 12 may be reduced. Moreover, when an end of the top cell or an end of the bottom cell is exposed to the outside, the isolation voltage between the top cell and the bottom cell may be reduced, and the isolation voltage between the top cell and the outside structure or between the bottom cell and the outside structure may be reduced, due to moisture such as rain.

Furthermore, when an inter-cell connecting electrode 16 which connects the top cell and the bottom cell or terminal electrodes 18a and 18b for extracting electric power from the top cell and the bottom cell are exposed to the outside, reliability of the photovoltaic device may be reduced due to corrosion of the electrode or the like, which may become problematic. In addition, when the structure is formed into modules, the isolation voltage between the module and a metal frame or the like may be reduced.

### SUMMARY OF THE INVENTION

According to one aspect of the present invention, there is provided a photovoltaic device comprising a first photovoltaic unit in which a plurality of photovoltaic cells are connected in series in a first connecting direction over a first substrate which has an insulating surface and which is light-transmissive, a second photovoltaic unit in which a plurality of photovoltaic cells having an optical band gap which differs from that of the first photovoltaic unit are connected in series in a second connecting direction over a second substrate which has an insulating surface, wherein the first connecting direction and the second connecting direction are directions of flow of current, a light-transmissive inorganic insulating layer is formed over at least one of the first photovoltaic unit and the second photovoltaic unit, and the first photovoltaic unit and the second photovoltaic unit are fixed by a light-transmissive resin layer while the first photovoltaic unit and the second photovoltaic unit are opposed to each other with the first connecting direction and the second connecting direction being opposite directions and the first substrate and the second substrate being at outer sides.

According to another aspect of the present invention, there is provided a method of manufacturing a photovoltaic device, comprising the steps of forming, over a first substrate which has an insulating surface and which is light-transmissive, a first photovoltaic unit in which a plurality of photovoltaic cells are connected in series in a first connecting direction, forming, over a second substrate which has an insulating surface, a second photovoltaic unit in which a plurality of photovoltaic cells having an optical band gap which differs from that of the first photovoltaic unit are connected in series in a second connecting direction, forming a light-transmissive inorganic insulating layer over at least one of the first photovoltaic unit and the second photovoltaic unit, forming an opening channel in the light-transmissive inorganic insulating layer, injecting a conductive material into the opening channel of the light-transmissive inorganic insulating layer, and fixing the first photovoltaic unit and the second photovoltaic unit with a light-transmissive resin layer therebetween, the light-transmissive resin layer having an opening channel corresponding to a position of the opening channel of the light-transmissive inorganic insulating layer, while the first connecting direction and the second connecting direction are directions of flow of current and the first photovoltaic unit and the second photovoltaic unit are opposed to each other with the first connecting direction and the second connecting direction being opposite directions and the first substrate and the second substrate being at outer sides.

According to another aspect of the present invention, there is provided a method of manufacturing a photovoltaic device, comprising the steps of forming, over a first substrate which has an insulating surface and which is light-transmissive, a first photovoltaic unit in which a plurality of photovoltaic cells are connected in series in a first connecting direction, forming, over a second substrate which has an insulating surface, a second photovoltaic unit in which a plurality of photovoltaic cells having an optical band gap which differs from that of the first photovoltaic unit are connected in series in a second connecting direction, forming a light-transmissive inorganic insulating layer over at least one of the first photovoltaic unit and the second photovoltaic unit, fixing the first photovoltaic unit and the second photovoltaic unit with a light-transmissive resin layer therebetween while the first connecting direction and the second connecting direction are directions of flow of current and the first photovoltaic unit and the second photovoltaic unit are opposed to each other with the first connecting direction and the second connecting direction being opposite directions and the first substrate and the second substrate being at outer sides, forming an opening channel from a side near the second substrate, and injecting a conductive material into the opening channel.

According to another aspect of the present invention, there is provided a photovoltaic device comprising a first photovoltaic unit in which a plurality of photovoltaic cells are connected in series in a first connecting direction over a first substrate which has an insulating surface and which is light-transmissive, and a second photovoltaic unit in which a plurality of photovoltaic cells having an optical band gap which differs from that of the first photovoltaic unit are connected in series in a second connecting direction over a second substrate which has an insulating surface, wherein the first connecting direction and the second connecting direction are directions of flow of current, the first photovoltaic unit and the second photovoltaic unit are fixed by a light-transmissive resin layer while the first photovoltaic unit and the second photovoltaic unit are opposed to each other with the first connecting direction and the second connecting direction being opposite directions and the first substrate and the second substrate being at outer sides, and a particle having an index of refraction which differs from that of a primary material of the light-transmissive resin layer is embedded in the light-transmissive resin layer.

According to another aspect of the present invention, there is provided a method of manufacturing a photovoltaic device, comprising the steps of forming, over a first substrate which has an insulating surface and which is light-transmissive, a first photovoltaic unit in which a plurality of photovoltaic cells are connected in series in a first connecting direction, forming, over a second substrate which has an insulating surface, a second photovoltaic unit in which a plurality of photovoltaic cells having an optical band gap which differs from that of the first photovoltaic unit are connected in series in a second connecting direction, and fixing the first photovoltaic unit and the second photovoltaic unit with a light-transmissive resin layer therebetween while the first connecting direction and the second connecting direction are directions of flow of current and the first photovoltaic unit and the second photovoltaic unit are opposed to each other with the first connecting direction and the second connecting direction being opposite directions and the first substrate and the second substrate being at outer sides, wherein a particle having an index of refraction which differs from that of a primary material of the light-transmissive resin layer is embedded in the light-transmissive resin layer.

### BRIEF DESCRIPTION OF THE DRAWINGS

A preferred embodiment of the present invention will be described in detail by reference to the drawings, wherein:

FIG. 1 is a cross-sectional diagram showing a structure of a photovoltaic device according to a preferred embodiment of the present invention;

FIG. 2 is a plan view showing a structure of a photovoltaic device according to a preferred embodiment of the present invention;

FIG. 3 is a diagram showing a method of forming a top cell in a preferred embodiment of the present invention;

FIG. 4 is a diagram showing a method of forming a bottom cell in a preferred embodiment of the present invention;

FIG. 5 is a flowchart of a method of determining areas of a top cell and a bottom cell in a preferred embodiment of the present invention;

FIG. 6 is a diagram showing a relationship between a thickness of an I layer of a bottom cell and an operation current density in a preferred embodiment of the present invention;

FIG. 7 is a diagram showing a method of forming a top cell in a preferred embodiment of the present invention;

FIG. 8 is a diagram showing a method of forming a bottom cell in a preferred embodiment of the present invention;

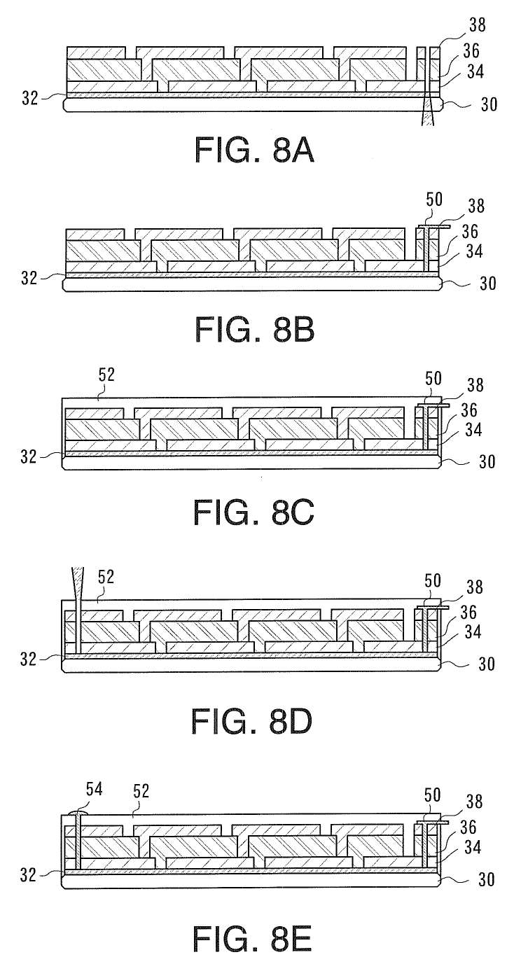

FIG. 9 is a diagram showing a method of layering a top cell and a bottom cell in a preferred embodiment of the present invention;

FIG. 10 is a diagram showing a method of forming a photovoltaic device according to a first alternative embodiment of the present invention;

FIG. 11 is a diagram showing a structure of a photovoltaic device according to a first alternative embodiment of the present invention; and

FIG. 12 is a diagram showing a structure of a photovoltaic device of related art.

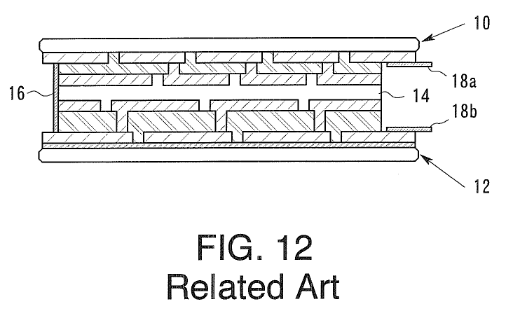

### DESCRIPTION OF THE PREFERRED EMBODIMENTS

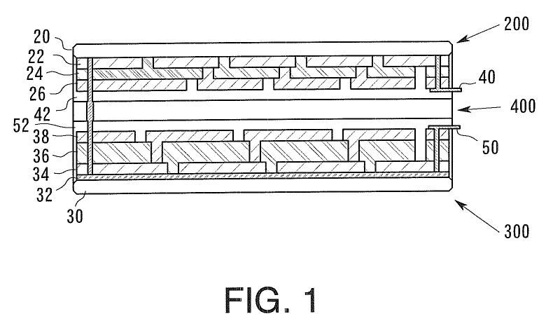

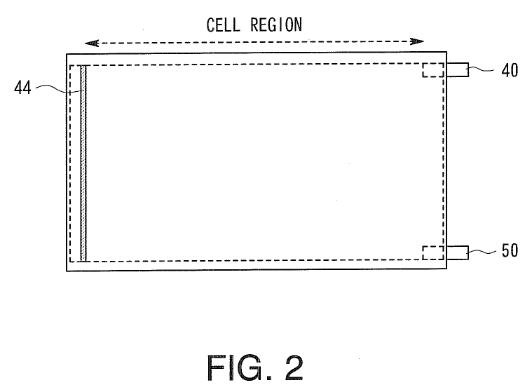

FIG. 1 is a schematic cross-sectional diagram showing a layered photovoltaic device according to a preferred embodiment of the present invention. FIG. 2 is a schematic cross-sectional diagram showing a layered photovoltaic device according to a preferred embodiment of the present invention.

The photovoltaic device according to the preferred embodiment of the present invention is of a tandem type in which an amorphous silicon (a-Si) (opto-electric conversion) unit 200 having a wide band gap is provided at a top side which is the side of incidence of light and a microcrystalline silicon (μc-Si) (opto-electric conversion) unit 300 having a narrower band gap than the a-Si unit 200 is provided at a bottom side. The a-Si unit 200 at the top side and the μc-Si unit 300 at the bottom side are layered while being opposed to each other with the substrates at outer positions, with a light-transmissive resin layer 400 therebetween, the light-transmissive resin layer 400 being made of a material such as a polyimide film, an epoxy resin, etc.

Here, the a-Si unit 200 and the μc-Si unit 300 are placed so that the connecting directions of photovoltaic cells are opposite to each other and the directions of flow of current are opposite to each other.

However, the present invention is not limited to such a configuration, and the present invention can be applied to any photovoltaic device (solar battery module) having a structure in which a plurality of opto-electric conversion cells are layered.

Here, it is preferable to adjust the areas of the a-Si cell and the μc-Si cell by increasing the area of the a-Si cell having a lower operation current density so that the same operation current flows in the a-Si cell as in the μc-Si cell. In other words, when the optimum operation current density of the a-Si cell at the top side is Jop1, the area of one cell of the a-Si cell is S1, the optimum operation current density of the μc-Si cell at the bottom side is Jop2, and the area of one cell of the μc-Si cell is S2, it is preferable to configure such that a relationship of Jop1×S1=Jop2×S2 is satisfied.

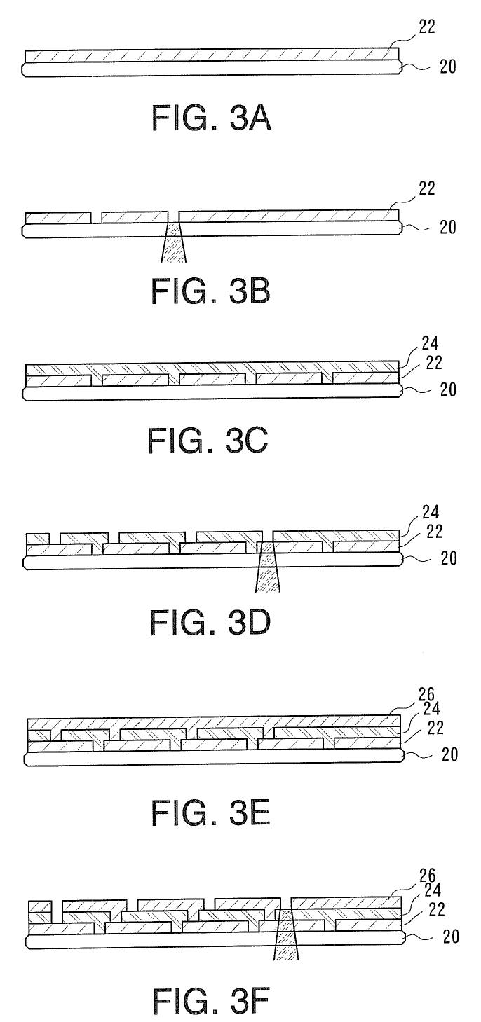

FIG. 3 shows a formation process of the a-Si unit 200 at the topside. The a-Si unit 200 at the top side is formed over a transparent insulating substrate 20. The a-Si unit 200 is formed with a plurality of units integrated in a predetermined area. The transparent insulating substrate 20 may be, for example, a glass substrate, a plastic substrate, or the like.

A transparent electrode 20 is formed over the transparent insulating substrate 20 (FIG. 3A). For the transparent electrode 22, a transparent conductive oxide (TCO) such as, for example, tin oxide (SnO₂), zinc oxide (ZnO), and indium tin oxide (ITO) is used. The transparent electrode 22 can be formed, for example, through sputtering or the like. A thickness of the transparent electrode 22 is preferably set in a range of greater than or equal to 10 nm and less than or equal to 200 nm. In addition, it is preferable to provide projections and recesses having a light confinement effect on an upper surface of the transparent electrode 22. The transparent electrode 22 is separated and machined for each predetermined cell using YAG laser or the like (FIG. 3B).

An amorphous silicon semiconductor layer 24 in which amorphous silicon films of a P-type layer, an I-type layer, and an N-type layer are sequentially layered is formed over the transparent electrode 22 (FIG. 3C). For example, with the conditions shown in TABLE 1, an amorphous silicon semiconductor layer 24 having a P-type amorphous silicon carbide layer having a thickness of approximately 5 nm, an I-type amorphous silicon layer having a thickness of 0.2 μm, and an N-type amorphous silicon layer having a thickness of approximately 5 nm is formed.

TABLE 1

| | | FILM |
|---|---|---|
| | | FORMATION |
| | | CONDITION |
| RF POWER (mW/cm²) | | 30 |
| SUBSTRATE | | 200 |
| TEMPERATURE (° C.) | | |
| PRESSURE (Pa) | | 50 |
| REACTION | P-LAYER | SiH₄: 10 |
| GAS | | CH₄: 15 |
| (sccm) | | B₂H₆: 0.1 |
| | | H₂: 200 |
| | I-LAYER | SiH₄: 50 |
| | | H₂: 50 |
| | N-LAYER | SiH₄: 10 |
| | | PH₃: 0.1 |
| | | H₂: 10 |

Laser separation and machining is applied to the amorphous silicon semiconductor layer 24 at a location next to slits which separate the transparent electrode 22, to separate and machine the amorphous silicon semiconductor layer 24 (FIG. 3D). For example, positions distanced from the slits which separate the transparent electrode 22 by 50 μm are separated and machined along the slit of the transparent electrode 22. In addition, the laser separation and machining is applied near the end of the amorphous silicon semiconductor layer 24, to form an ineffective region for forming the slit in which an electrode exit section is to be embedded and which does not contribute to power generation.

A transparent electrode 26 of the back side is formed over the amorphous silicon semiconductor layer 24 (FIG. 3E). For the transparent electrode 26, a transparent conductive oxide (TCO) such as, for example, tin oxide (SnO²), zinc oxide (ZnO), and indium tin oxide (ITO) is used. The transparent electrode 26 may be formed, for example, through sputtering or the like. The thickness of the transparent electrode 26 is preferably in a range of greater than or equal to 10 nm and less than or equal to 200 nm.

A laser separation and machining is applied to the transparent electrode 26 at locations next to the slits of the amorphous silicon semiconductor layer 24, to form slits, and the transparent electrode 26 is separated and machined in a strap shape (FIG. 3F). For example, positions distanced from the slits of the amorphous silicon semiconductor layer 24 in a side opposite to the slits of the transparent electrode 22 by 50 μm are separated and machined along the slits of the amorphous silicon semiconductor layer 24. With this process, the transparent electrode 26 is connected to the transparent electrodes 22 on the side of light incidence of the adjacent a-Si cell, and adjacent a-Si cells are connected in series. In addition, laser separation and machining is applied near the end of the transparent electrode 26, to form slits which overlap the slits formed in the ineffective region of the amorphous silicon semiconductor layer 24.

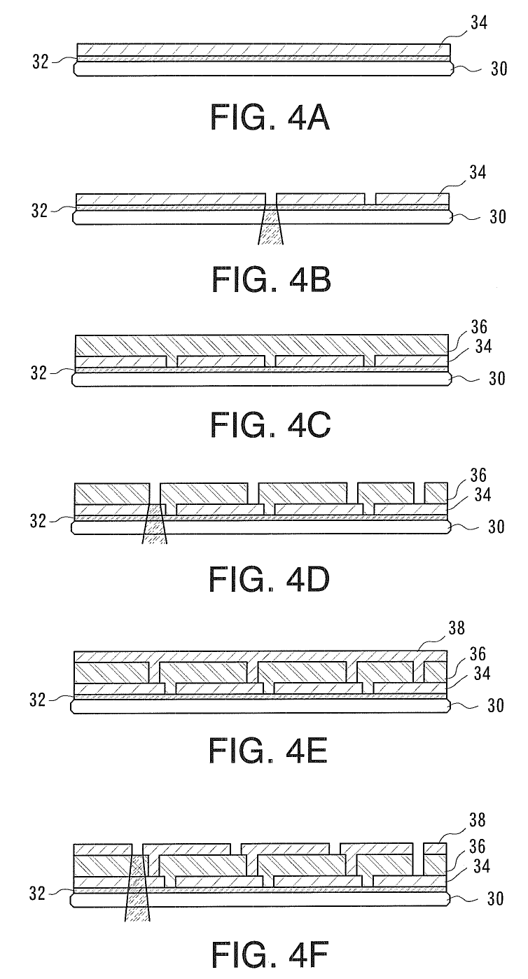

FIG. 4 shows a formation process of the μc-Si unit 300 at the bottom side. The μc-Si unit 300 at the bottom side is formed over a substrate in which a transparent insulating layer 32 made of a material such as polyimide, silicon oxide (SiO₂), or the like is formed over a substrate 30 made of stainless steel or the like through a thermal CVD method or the like (FIG. 4A).

A layered structure of a reflective metal and a transparent conductive oxide (TCO) is formed as a back side electrode 34 over the transparent insulating layer 32 (FIG. 4A). For the reflective metal, a metal such as silver (Ag), aluminum (Al), etc. may be used. As the material for the TCO, a transparent conductive oxide (TCO) such as tin oxide (SnO₂), zinc oxide (ZnO), indium tin oxide (ITO), or the like may be used. The TCO may be formed, for example, through sputtering or the like. The thickness of the back side electrode 34 is preferably approximately 1 μm. The reflective metal film is placed on a side near the transparent insulating layer 32, and the TCO film is placed on a side near the microcrystalline silicon semiconductor layer 36. It is preferable that projections and recesses for improving the light confinement effect are provided on at least one of the reflective metal film and the TCO film. The back side electrode 34 is separated and machined for each predetermined cell using YAG laser or the like (FIG. 4B).

A microcrystalline silicon semiconductor layer 36 in which microcrystalline silicon films of a P-type layer, an I-type layer, and an N-type layer are sequentially layered is formed over the backside electrode 34 (FIG. 4C). For example, with the conditions shown in TABLE 2, the microcrystalline silicon semiconductor layer 36 having an N-type microcrystalline silicon layer having a thickness of approximately 5 nm, an I-type microcrystalline silicon layer having a thickness of 2.4 μm, and a P-type microcrystalline silicon carbide layer having a thickness of approximately 5 nm is formed through an RF plasma CVD method.

TABLE 2

| | | FILM |
|---|---|---|
| | | FORMATION |
| | | CONDITION |
| RF POWER (mW/cm²) | | 30~100 |
| SUBSTRATE | | 180~250 |
| TEMPERATURE (° C.) | | |
| PRESSURE (Pa) | | 50~100 |
| REACTION | P-LAYER | SiH₄: 10 |
| GAS | | CH₄: 15 |
| (sccm) | | B₂H₆: 0.1 |
| | | H₂: 200 |
| | I-LAYER | SiH₄: 10 |
| | | H₂: 200 |
| | N-LAYER | SiH₄: 10 |
| | | PH₃: 0.1 |
| | | H₂: 10 |

In addition, laser separation and machining is applied on the microcrystalline silicon semiconductor layer 36 at locations next to the slits which separate the back side electrode 34, to separate and machine the microcrystalline silicon semiconductor layer 36. For example, positions distanced from the slits which separate the backside electrode 34 by 50 μm are separated and machined along the slits of the back side electrode 34 (FIG. 4D). Moreover, laser separation and machining is applied near an end of the microcrystalline silicon semiconductor layer 36, to form an ineffective region for forming slits in which an electrode exit portion is to be embedded and which does not contribute to power generation. The ineffective region formed in the μc-Si unit 300 is formed at a position opposing the ineffective region of the a-Si unit 200 when the μc-Si unit 300 and the a-Si unit 200 are joined.

A transparent electrode 38 on a front surface side is formed over the microcrystalline silicon semiconductor layer 36 (FIG. 4E). For the transparent electrode 38, a transparent conductive oxide (TCO) such as tin oxide (SnO₂), zinc oxide (ZnO), indium tin oxide (ITO), or the like is used. The transparent electrode 38 may be formed, for example, through sputtering. The thickness of the transparent electrode 38 is preferably in a range of greater than or equal to 10 nm and less than or equal to 200 nm.

Laser separation and machining is applied on the transparent electrode 38 at locations next to the slits of the microcrystalline silicon semiconductor layer 36, to form slits, and the transparent electrode 38 is separated and machined in a strap shape (FIG. 4F). For example, positions distanced from the slits of the microcrystalline silicon semiconductor layer 36 on the side opposite to that of the slits of the back side electrode 34 by 50 μm are separated and machined along the slits of the microcrystalline silicon semiconductor layer 36. With this process, the transparent electrode 38 is connected to the back side electrode 34 of the back side of the adjacent μc-Si cell and the adjacent μc-Si cells are connected in series. In addition, laser separation and machining is applied near an end of the transparent electrode 38, to form slits which overlap the slits formed in the ineffective region of the microcrystalline silicon semiconductor layer 36.

Here, in the a-Si unit 200 and the μc-Si unit 300, the areas of the cells are varied to adjust the size of the current, and the cells are connected in series so that all solar batteries operate at an optimum operation current density. Between the case where the optimum operation currents Jop1 and Jop2 of the a-Si cell and the μc-Si cell differ from each other and the case where the optimum operation currents Jop1 and Jop2 match, the case where the optimum operation currents Jop1 and Jop2 differ from each other has a higher internal quantum efficiency. Therefore, the cell areas of the a-Si cell and the μc-Si cell are set so that the optimum operation currents Jop1 and Jop2 differ from each other.

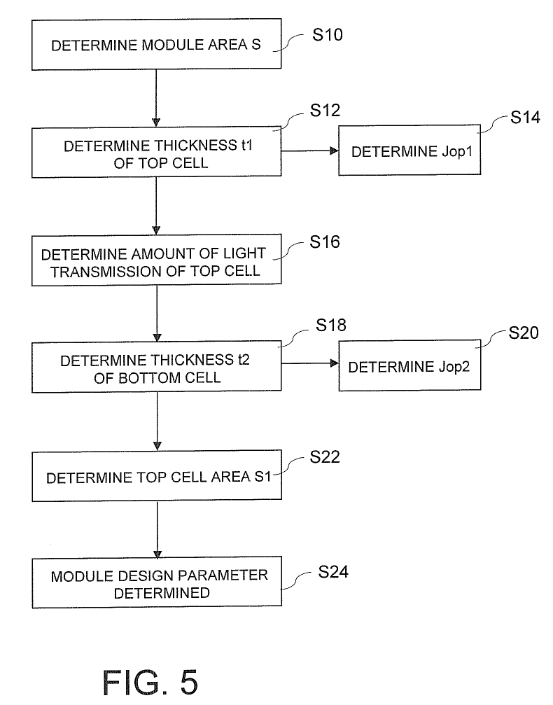

FIG. 5 is a flowchart showing a method of determining the thicknesses and cell areas of the a-Si cell which is the top cell and the μc-Si cell which is the bottom cell. This process is targeted to set the relationship between the operation current density Jop2 (mA/cm) of the bottom cell and the operation current density Jop1 (mA/cm) of the top cell to Jop2=2×Jop1 and the relationship between the area S1 (cm²) of the top cell and the area S2 (cm²) of the bottom cell to S1=0.5×S2.

An area S of the module is determined in step S10. Here, the area is set to 10 cm×10 cm.

A thickness of the I layer of the a-Si unit 200 which is at the top side is determined in step S12. A thickness t1 of the I layer of the a-Si cell 200 is set to a thickness having a sufficiently low light degradation. Here, the thickness is set to 0.2 μm (or less) under a condition that the degradation percentage is less than or equal to 10%.

The operation current density Jop1 of the a-Si cell is determined in step S14. An a-Si unit 200 having an effective area of 1 cm×1 cm is generated with the thickness of the I layer set to 0.2 μm, and the generated sample is measured by a solar simulator (AM1.5, 100 mW/cm) for a current-voltage characteristic of the cell. With this process, the operation current density Jop1 of the top cell is determined. The operation current density is set as a current value at a maximum point of output power (current×voltage) calculated based on the current-voltage characteristic. Here, Jop1 is assumed to be Jop1=8.1 mA/cm for the purpose of description.

The formation condition of the sample in this case is preferably set as the same formation condition as that during the actual formation of the module. However, the integrated structure is not formed, and a structure with the same light transmittance is created. In addition, in order to simulate the structure of the actual device during measurement, that is, in order to consider the influence of the reflected light from the μc-Si unit 300 which is at the bottom side, the μc-Si unit 300 is placed below the sample a-Si unit 200. For the μc-Si unit 300, the μc-Si unit 300 formed in the next step S18 is used.

A thickness t2 of the I layer of the μc-Si unit 300 is initially arbitrarily selected. Because the thickness t2 is determined after the process of step S18 is executed, in reality, the processes of steps S12 to S18 are repeated several times.

An amount of light transmission of the a-Si unit 200 is determined in step S16. The a-Si unit 200 having the thickness (t1) of the I layer determined in step S12 is formed. The a-Si unit 200 is placed over the μc-Si unit 300 and the current-voltage characteristic of the μc-Si unit 300 is measured. A plurality of the μc-Si units 300 are prepared with the cell area of 1 cm×1 cm and the thickness t2 of the I layer in a range of 1.0 μm˜3.0 μm. In this process, the μc-Si unit 300 is created under the same formation conditions as when the actual module is created.

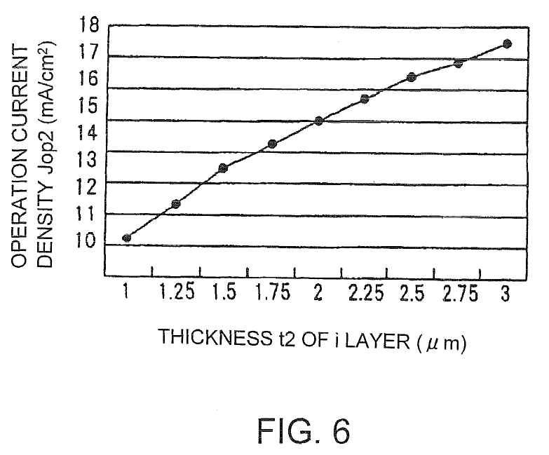

With the a-Si unit 200 placed over the μc-Si unit 300, the current-voltage characteristic of the μc-Si unit 300 is measured with a solar simulator (AM1.5, 100 mW/cm). With this process, the light transmitted from the a-Si unit 200 is incident on the μc-Si unit 300, and a power generation characteristic under the actual usage conditions can be measured. FIG. 6 shows a relationship between the thickness t2 of the I layer of the μc-Si unit 300 and the operation current density Jop2.

In step S18, a minimum value of the thickness t2 of the I layer is searched which satisfies a target based on the thickness dependency of the operation current density measured in step S16 and which satisfies the condition with regard to the operation current density Jop2 of μc-Si cell that Jop2=2×Jop1.

In step S20, because it is found based on FIG. 6 that the thickness t2 of the I layer must be greater than or equal to 2.4 μm, it is determined that t2=2.4 μm and Jop2=16.2 mA/cm. When no value of t2 which satisfies the target can be obtained, the value of t1 and the range of t2 must be reviewed.

The area S1 of the a-Si cell is determined in step S22. Because the area S2 of the μc-Si cell is determined as S2=10 cm×2.5 cm, the continuation relationship of the current flowing between layers in which the cells are connected in series is set to satisfy the relationship of Jop2×S2=Jop1×S1, that is, S1=10 cm×5 cm.

With this process, in step S24, it is determined that S1=10 cm×5 cm, S2=10 cm×2.5 cm, Jop1=8.1 mA/cm, and Jop2=16.2 mA/cm.

With the above-described processes, the thicknesses and cell areas of the a-Si unit 200 and the μc-Si unit 300 are determined, and the a-Si unit 200 and the μc-Si unit 300 are formed to satisfy the determined values.

By determining the thicknesses and cell areas of the a-Si unit 200 and the μc-Si unit 300 through the above-described processes, it is possible to increase the degree of freedom in design and manufacture of the photovoltaic device, and to form the photovoltaic device with conditions, and values such as operation current density, amount of light transmission, thickness, etc., which tend to not be affected by the light degradation or the like.

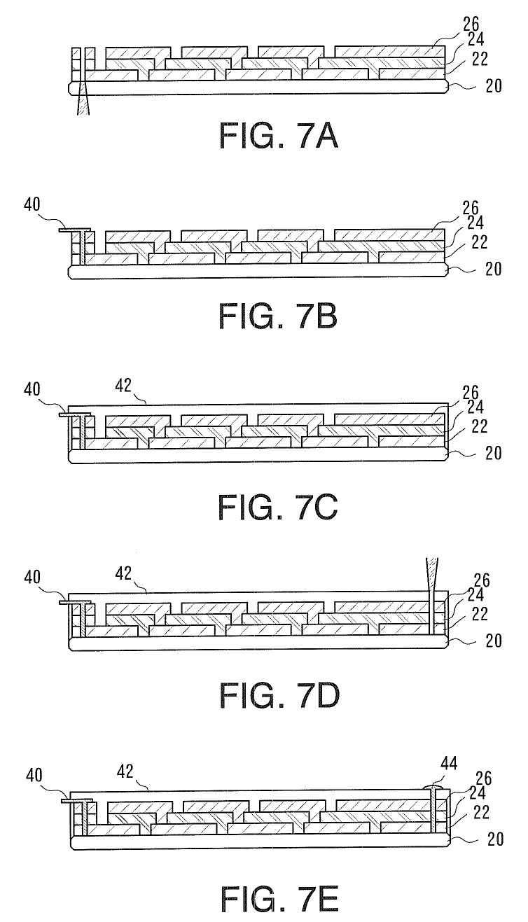

Next, a process to form a coupler type structure by layering the a-Si unit 200 and the μc-Si unit 300 which are formed will be described. FIG. 7 shows the process when the coupler-type structure is formed.

An electrode exit section 40 is formed in the a-Si unit 200. YAG laser or the like is used from the side of the transparent insulating substrate 20, to form slits for embedding the electrode exit section 40 in the transparent electrode 22, amorphous silicon semiconductor layer 24, and transparent electrode 26 (FIG. 7A). The slits are formed in the ineffective region of the a-Si unit 200 near the end of the transparent insulating substrate 20. A metal paste is embedded in the slit, and an electrode exit section 40 is formed in the end direction along the transparent electrode 26, connected to the embedded portion (FIG. 7B). For the metal paste, a silver paste in which silver is mixed with an organic binder or the like may be used.

After the electrode exit section 40 is formed, a light-transmissive inorganic insulating layer 42 is formed covering the transparent electrode 22, amorphous silicon semiconductor layer 24, and transparent electrode 26 (FIG. 7C). The light-transmissive inorganic insulating layer 42 is formed to cover at least a part of the electrode exit section 40 so that at least a part of the electrode exit section 40 protrudes.

The material of the light-transmissive inorganic insulating layer 42 is preferably a silicon oxide film (SiO₂), titanium oxide (TiO₂), alumina (Al₂O₃), etc. The light-transmissive inorganic insulating layer 42 may be formed, for example, through sputtering or coating. The thickness of the light-transmissive inorganic insulating layer 42 is set to be greater than or equal to 1 μm to secure humidity resistance, and less than or equal to 10 μm so that the absorption loss can be ignored. Desirably, the thickness of the light-transmissive inorganic insulating layer 42 is preferably set to greater than or equal to 2 μm and less than or equal to 5 μm.

Then, slits for inter-cell connecting electrodes are formed in the transparent electrode 22, amorphous silicon semiconductor layer 24, transparent electrode 26, and light-transmissive inorganic insulating layer 42 (FIG. 7D). Here, slits are formed using YAG laser from the side of the light-transmissive inorganic insulating layer 42. The slit is formed near an end of the transparent insulating substrate 20 at a side opposite to that of the electrode exit section 40. A metal paste is embedded in the slit, to form the inter-cell connecting electrode 44 (FIG. 7E). For the metal paste, a silver paste in which silver is mixed to an organic binder or the like may be used.

Similar processes are applied to the μc-Si unit 300. An electrode exit section 50 is formed in the μc-Si unit 300. Slits for embedding the electrode exit section 50 are formed in the back side electrode 34, microcrystalline silicon semiconductor layer 36, and transparent electrode 38 using YAG laser or the like. The slit is formed in the ineffective region of the μc-Si unit 300 near an end of the substrate 30. A metal paste is embedded in the slit, and the electrode exit section 50 is formed in the end direction along the transparent electrode 38, connected to the embedded portion. For the metal paste, silver paste in which silver is mixed with an organic binder or the like may be used.

After the electrode exit section 50 is formed, a light-transmissive inorganic insulating layer 52 is formed covering the back side electrode 34, microcrystalline silicon semiconductor layer 36, and transparent electrode 38. The light-transmissive inorganic insulating layer 52 is formed covering a part of the electrode exit section 50 so that at least a part of the electrode exit section 50 protrudes.

The material of the light-transmissive inorganic insulating layer 52 is preferably a silicon oxide film (SiO₂), titanium oxide (TiO₂), alumina (Al₂O₃), or the like. The light-transmissive inorganic insulating layer 52 may be formed, for example, through sputtering or coating. The thickness of the light-transmissive inorganic insulating layer 52 is set to greater than or equal to 1 μm to secure humidity resistance, and less than or equal to 10 μm so that the absorption loss can be ignored. Desirably, the thickness of the light-transmissive inorganic insulating layer 52 is set to greater than or equal to 2 μm and less than or equal to 5 μm.

Then, slits for inter-cell connecting electrode are formed in the backside electrode 34, microcrystalline silicon semiconductor layer 36, transparent electrode 38, and light-transmissive inorganic insulating layer 52. Here, the slits are formed using YAG laser from the side of the light-transmissive inorganic insulating layer 52. The slit is formed near an end of the substrate 30 at the opposite side as the electrode exit section 50. A metal paste is embedded in the slit, and the inter-cell connecting electrode 54 is formed. For the metal paste, a silver paste in which silver is mixed with an organic binder or the like may be used.

The a-Si unit 200 and the μc-Si unit 300 thus formed are fixed by a light-transmissive resin layer 400. For the light-transmissive resin layer 400, for example, polyethylene terephthalate (PET), ethylene vinyl acetate (EVA), or the like may be used.

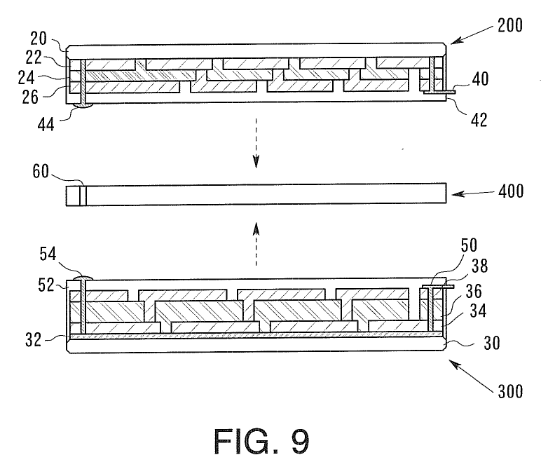

As shown in FIG. 9, the a-Si unit 200 and the μc-Si unit 300 are placed such that the connecting directions of the photovoltaic cells are opposite to each other and the directions of flow of current are opposite to each other. The a-Si unit 200 and the μc-Si unit 300 are fixed with the light-transmissive resin layer 400 therebetween while being opposed to each other with the transparent insulating substrate 20 and substrate 30 at outer positions. A slit 60 is formed in the light-transmissive resin layer 400 at positions corresponding to the inter-cell connecting electrode 44 provided in the a-Si unit 200 and the inter-cell connecting electrode 54 provided in the μc-Si unit 300. The slit 60 can be formed using laser or the like. The width of the slit 60 is preferably set wider than the inter-cell connecting electrode 44 and the inter-cell connecting electrode 54.

Here, the electrode exit section 40 on the side of the a-Si unit 200 and the electrode exit section 50 on the side of the μc-Si unit 300 are set to oppose each other. In addition, the inter-cell connecting electrode 44 on the side of the a-Si unit 200 and the inter-cell connecting electrode 54 on the side of the μc-Si unit 300 are set opposing each other, with the slit 60 of the light-transmissive resin layer 400 positioned between the inter-cell connecting electrode 44 and the inter-cell connecting electrode 54.

In this state, thermal compression bonding is applied. Because of the thermoplasticity of the light-transmissive resin layer 400, the light-transmissive resin layer 400 is softened between the a-Si unit 200 and the μc-Si unit 300, and then, with cooling, the fluidity is lost and the light-transmissive resin layer 400 is hardened. With this process, the a-Si unit 200 and the μc-Si unit 300 are fixed by the light-transmissive resin layer 400, as shown in FIG. 1.

The inter-cell connecting electrode 44 formed in the a-Si unit 200 and the inter-cell connecting electrode 54 formed in the μc-Si unit 300 are also fluidized by heating, the metal paste is filled in the slit 60 provided on the light-transmissive resin layer 400, and the inter-cell connecting electrode 44 and the inter-cell connecting electrode 54 are electrically connected.

In the present embodiment, the slits are formed through laser machining, but the present invention is not limited to such a configuration, and the slit may alternatively be formed by a mechanical method such as dicing saw.

In this manner, the layered photovoltaic device of the present embodiment can be formed. In the layered photovoltaic device according to the present embodiment, the inter-cell connecting electrode 44 and the inter-cell connecting electrode 54 are not exposed to the outside and are protected by the light-transmissive inorganic insulating layer 42, light-transmissive inorganic insulating layer 52, and light-transmissive resin layer 400. Thus, even if the thicknesses are thinned, the isolation voltage between the top cell and the bottom cell can be maintained at a high value. In addition, because at least a part of the electrode exit section 40 and the electrode exit section 50 is protected by the light-transmissive inorganic insulating layer 42 and the light-transmissive inorganic insulating layer 52, it is possible to inhibit reduction in the isolation voltage between the top cell and the bottom cell and reduction in the isolation voltage between the top cell and the outside or bottom cell and the outside due to moisture such as rain.

In the present embodiment, the light-transmissive inorganic insulating layer 42 and the light-transmissive inorganic insulating layer 52 are formed over both the a-Si unit 200 and the μc-Si unit 300. Alternatively, it is also possible to form the light-transmissive inorganic insulating layer over one of the a-Si unit 200 and the μc-Si unit 300.

In addition, although the present embodiment has been described exemplifying the tandem-type photovoltaic device having the a-Si unit 200 and the μc-Si unit 300, the structure of the present embodiment can be similarly applied to coupler-type photovoltaic devices other than the tandem type. Moreover, the structure of the present embodiment can be similarly applied to photovoltaic devices in which three or more photovoltaic units are layered.

### First Alternative Embodiment

In the above-described preferred embodiment, the slits provided for the inter-cell connecting electrodes for connecting the a-Si unit 200 which is at the top side and the μc-Si unit 300 which is at the bottom side are formed before the a-Si unit 200 and the μc-Si unit 300 are fixed. Alternatively, it is also preferable to form the slits after the a-Si unit 200 and the μc-Si unit 300 are fixed.

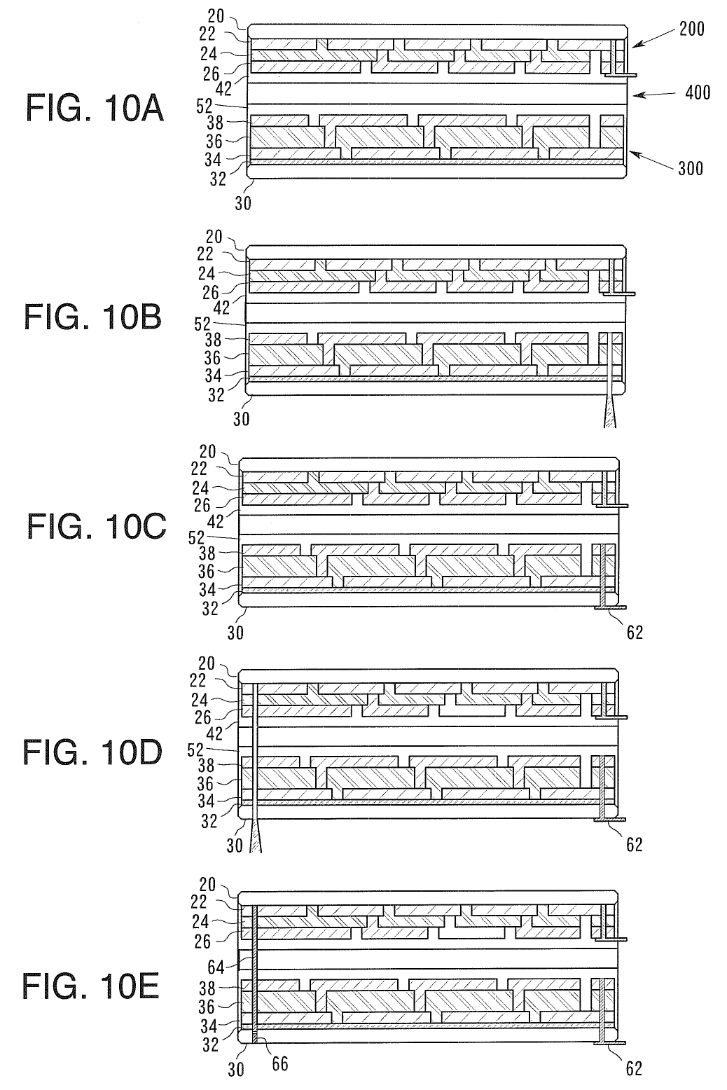

FIG. 10 shows a forming method of a layered photovoltaic device in the present alternative embodiment. In this configuration, the a-Si unit 200 and the μc-Si unit 300 are fixed before the slits for providing the inter-cell connecting electrode are formed. In addition, the electrode exit section 50 is not formed in the μc-Si unit 300 (FIG. 10A).

After the a-Si unit 200 and the μc-Si unit 300 are fixed, the electrode exit section 50 is formed in the μc-Si unit 300. Slits for embedding the electrode exit section 50 are formed using YAG laser or the like, from the side of the substrate 30, in the substrate 30, back side electrode 34, microcrystalline silicon semiconductor layer 36, and transparent electrode 38 (FIG. 10B). The slits are formed in the ineffective region of the μc-Si unit 300 near the end of the substrate 30. In the case of the present alternative embodiment, the substrate 30 of the μc-Si unit 300 which is the bottom cell is preferably made of plastic which can be easily machined.

A metal paste is embedded in the slit, and an electrode exit section 62 is formed in the end direction along the transparent electrode 38, connected to the embedded portion (FIG. 10C). For the metal paste, a silver paste in which silver is mixed with an organic binder or the like may be used.

Then, slits for inter-cell connecting electrode are formed in the transparent electrode 22, the amorphous silicon semiconductor layer 24, the transparent electrode 26, the light-transmissive inorganic insulating layer 42, the light-transmissive resin layer 400, the light-transmissive inorganic insulating layer 52, the transparent electrode 38, the microcrystalline silicon semiconductor layer 36, and the back side electrode 34 (FIG. 10D). Here, the slits are formed using YAG laser from the side of the light-transmissive inorganic insulating layer 52. The slits are formed near an end of the substrate 30 at an opposite side from that of the electrode exit section 62. A metal paste is embedded in the slit, and an inter-cell connecting electrode 64 is formed (FIG. 10E). For the metal paste, a silver paste in which silver is mixed with an organic binder or the like may be used.

In the present alternative embodiment, preferably, the inter-cell connecting electrode 64 is not embedded over the entire length of the slit formed in the substrate 30, and the metal paste is preferably injected for a length sufficient to connect the a-Si unit 200 and the μc-Si unit 300. In addition, preferably, a resin 66 is embedded in the remaining space of the slit on the side of the substrate 30 (FIG. 10E). With this structure, the inter-cell connecting electrode 64 does not directly contact moisture or the like from the outside, and occurrence of problem such as contact deficiency can be inhibited.

In this manner, the layered photovoltaic device of the present alternative embodiment can be formed. In the layered photovoltaic device of the present alternative embodiment also, because the inter-cell connecting electrode 64 is not exposed to the outside and is protected by the light-transmissive inorganic insulating layer 42, light-transmissive inorganic insulating layer 52, and light-transmissive resin layer 400, it is possible to maintain the isolation voltage between the top cell and the bottom cell at a high value even when these structures are thinned. In addition, because the electrode exit section 40 and the electrode exit section 62 are also protected by the light-transmissive inorganic insulating layer 42 and the light-transmissive inorganic insulating layer 52, it is possible to inhibit reduction of the isolation voltage between the top cell and the bottom cell and reduction in isolation voltage between the top cell and the outside or the bottom cell and the outside due to moisture such as rain or the like.

Moreover, because the electrode exit section 62 is formed on the side of the substrate 30 which is the back side of the layered photovoltaic device, lines can be easily extended from the electrode exit section 62 to the side of the substrate 30 when the devices are formed into a module.

### Second Alternative Embodiment

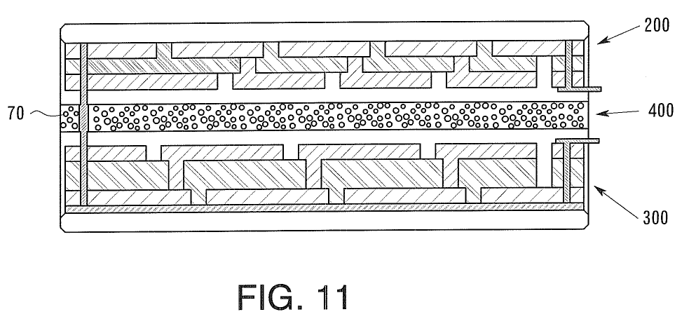

FIG. 11 is a cross-sectional diagram of a layered photovoltaic device according to a second alternative embodiment of the present invention. In the layered photovoltaic device of the present alternative embodiment, a filler 70 is mixed into the light-transmissive resin layer 400. The filler 70 is made of a material having an index of refraction which differs from that of a primary material of the light-transmissive resin layer 400. More specifically, it is preferable to set the index of refraction of the filler 70 to be greater than that of the primary material of the light-transmissive resin layer 400. For example, when polyethylene terephthalate (PET) or ethylene vinyl acetate (EVA) is used for the light-transmissive resin layer 400, it is preferable to mix glass micro-beads or the like as the filler 70. The diameter of the filler 70 is preferably set to greater than or equal to 0.1 μm and less than or equal to 10 μm, and more preferably set to greater than or equal to 0.5 μm and less than or equal to 2 μm.

By mixing the filler 70 in the light-transmissive resin layer 400 in this manner, it is possible to scatter, with the filler 70, the light transmitting through the a-Si unit 200 which is the top cell so that the optical path length of the light entering the a-Si unit 200 and the μc-Si unit 300 can be elongated. With this structure, the power generation efficiency of the layered photovoltaic device can be improved.

The present alternative embodiment can be applied to both the preferred embodiment and the first alternative embodiment described above, and in addition, to any layered photovoltaic device constructed by layering a plurality of cells. That is, by fixing the cells with the light-transmissive resin layer 400 during the layering of the cells and mixing the filer 70 in the light-transmissive resin layer 400, it is possible to obtain similar advantages and effects.

What is claimed is:

1. A photovoltaic device comprising:
a first photovoltaic unit in which a plurality of photovoltaic cells are connected in series in a first connecting direction over a first substrate which has an insulating surface and which is light-transmissive; and
a second photovoltaic unit in which a plurality of photovoltaic cells having an optical band gap which differs from that of the first photovoltaic unit are connected in series in a second connecting direction over a second substrate which has an insulating surface, wherein
the first connecting direction and the second connecting direction are directions of flow of current;
a light-transmissive inorganic insulating layer is formed over at least one of the first photovoltaic unit and the second photovoltaic unit, and
the first photovoltaic unit and the second photovoltaic unit are fixed by a light-transmissive resin layer while the first photovoltaic unit and the second photovoltaic unit are opposed to each other with the first connecting direction and the second connecting direction being opposite directions and the first substrate and the second substrate being at outer sides.

2. The photovoltaic device according to claim 1, wherein
an opening channel is formed in the light-transmissive inorganic insulating layer and the light-transmissive resin layer, and
the first photovoltaic unit and the second photovoltaic unit are electrically connected by a conductive material embedded in the opening channel and at a position at an end of the first photovoltaic unit and the second photovoltaic unit which is not exposed to an external environment.

3. The photovoltaic device according to claim 1, wherein
the light-transmissive inorganic insulating layer or the light-transmissive resin layer is formed to cover an end of the first photovoltaic unit or the second photovoltaic unit.

4. The photovoltaic device according to claim 2, wherein
a current extracting electrode which is conductive is provided from at least one of the first photovoltaic unit and the second photovoltaic unit at an end which is at an opposite side from the end in which the conductive material is embedded, and
at least a part of the current extracting electrode is covered by the light-transmissive inorganic insulating layer or the light-transmissive resin layer.

5. The photovoltaic device according to claim 1, wherein
a particle having an index of refraction which differs from that of a primary material of the light-transmissive resin layer is embedded in the light-transmissive resin layer.

6. A method of manufacturing a photovoltaic device, comprising the steps of:
forming, over a first substrate which has an insulating surface and which is light-transmissive, a first photovoltaic unit in which a plurality of photovoltaic cells are connected in series in a first connecting direction;
forming, over a second substrate which has an insulating surface, a second photovoltaic unit in which a plurality of photovoltaic cells having an optical band gap which differs from that of the first photovoltaic unit are connected in series in a second connecting direction;
forming a light-transmissive inorganic insulating layer over at least one of the first photovoltaic unit and the second photovoltaic unit;
forming an opening channel in the light-transmissive inorganic insulating layer;
injecting a conductive material into the opening channel of the light-transmissive inorganic insulating layer; and
fixing the first photovoltaic unit and the second photovoltaic unit with a light-transmissive resin layer therebetween, the light-transmissive resin layer having an opening channel corresponding to a position of the opening channel of the light-transmissive inorganic insulating layer, while the first connecting direction and the second connecting direction are directions of flow of current and the first photovoltaic unit and the second photovoltaic unit are opposed to each other with the first connecting direction and the second connecting direction being opposite directions and the first substrate and the second substrate being at outer sides.

7. A method of manufacturing a photovoltaic device, comprising the steps of:
forming, over a first substrate which has an insulating surface and which is light-transmissive, a first photovoltaic unit in which a plurality of photovoltaic cells are connected in series in a first connecting direction;
forming, over a second substrate which has an insulating surface, a second photovoltaic unit in which a plurality of photovoltaic cells having an optical band gap which differs from that of the first photovoltaic unit are connected in series in a second connecting direction;
forming a light-transmissive inorganic insulating layer over at least one of the first photovoltaic unit and the second photovoltaic unit;
fixing the first photovoltaic unit and the second photovoltaic unit with a light-transmissive resin layer therebetween while the first connecting direction and the second connecting direction are directions of flow of current and the first photovoltaic unit and the second photovoltaic unit are opposed to each other with the first connecting direction and the second connecting direction being opposite directions and the first substrate and the second substrate being at outer sides;
forming an opening channel from a side near the second substrate; and
injecting a conductive material into the opening channel.

8. A photovoltaic device comprising:
a first photovoltaic unit in which a plurality of photovoltaic cells are connected in series in a first connecting direction over a first substrate which has an insulating surface and which is light-transmissive; and
a second photovoltaic unit in which a plurality of photovoltaic cells having an optical band gap which differs from that of the first photovoltaic unit are connected in series in a second connecting direction over a second substrate which has an insulating surface, wherein
the first connecting direction and the second connecting direction are directions of flow of current;
the first photovoltaic unit and the second photovoltaic unit are fixed by a light-transmissive resin layer while the first photovoltaic unit and the second photovoltaic unit are opposed to each other with the first connecting direction and the second connecting direction being opposite directions and the first substrate and the second substrate being at outer sides; and
particles having an index of refraction which differs from that of a primary material of the light-transmissive resin layer are embedded in the light-transmissive resin layer.

9. The photovoltaic device according to claim 8, wherein
a light-transmissive inorganic insulating layer is formed over at least one of the first photovoltaic unit and the second photovoltaic unit, and
the first photovoltaic unit and the second photovoltaic unit are fixed by the light-transmissive resin layer with the light-transmissive inorganic insulting layer therebetween.
